(19) United States
(12) Patent Application Publication
(10) Pub. No.: US 2012/0146071 A1
(43) Pub. Date: Jun. 14, 2012

(54) LIGHT EMITTING CHIP AND METHOD FOR MANUFACTURING THE SAME

(75) Inventor: JIAN-SHIHN TSANG, Tu-Cheng (TW)

(73) Assignee: HON HAI PRECISION INDUSTRY CO., LTD., Tu-Cheng (TW)

(21) Appl. No.: 13/015,550

(22) Filed: Jan. 27, 2011

(30) Foreign Application Priority Data
Dec. 13, 2010 (TW) 99143474

(51) Int. Cl. H01L 33/64; H01L 21/36

(52) U.S. Cl. 257/98; 438/29; 257/E33.075; 257/E21.461

(57) ABSTRACT

A light emitting chip includes a substrate, a heat conducting layer formed on the substrate, a light emitting structure and a connecting layer connecting the heat conducting layer with the light emitting structure. The heat conducting layer includes a plurality of spaced catalyst areas on the substrate and a plurality of carbon nanotube islands vertically grown from the catalyst areas. The light emitting structure includes a first semiconductor layer, a light emitting layer and a second semiconductor layer. A first transparent conductive layer and a current conducting layer are sandwiched between the first semiconductor layer and the connecting layer. A second transparent conductive layer is formed on the second semiconductor layer.

### BACKGROUND

1. Technical Field

The present disclosure relates to a light emitting chip and a method for manufacturing the light emitting chip, and more particularly, to a light emitting chip having carbon nanotubes for increasing heat dissipation capability thereof.

2. Description of Related Art

LEDs are widely used in various applications. An LED often includes an LED chip to emit light. A conventional LED chip includes a substrate, an N-type semiconductor layer, a light-emitting layer and a P-type semiconductor layer sequentially grown on the substrate. The substrate is generally made of sapphire (Al₂O₃) for providing the growing environment for the semiconductor layers. However, such sapphire substrate has a low heat conductive capability, whereby heat generated by the semiconductor layers cannot be timely and effectively dissipated.

What is needed, therefore, is a light emitting chip and a method for manufacturing the light emitting chip which can overcome the limitations described above.

### BRIEF DESCRIPTION OF THE DRAWINGS

Many aspects of the present disclosure can be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 shows a light emitting chip in accordance with a first embodiment of the present disclosure.

FIG. 2 shows a light emitting chip in accordance with a second embodiment of the present disclosure.

### DETAILED DESCRIPTION OF THE EMBODIMENTS

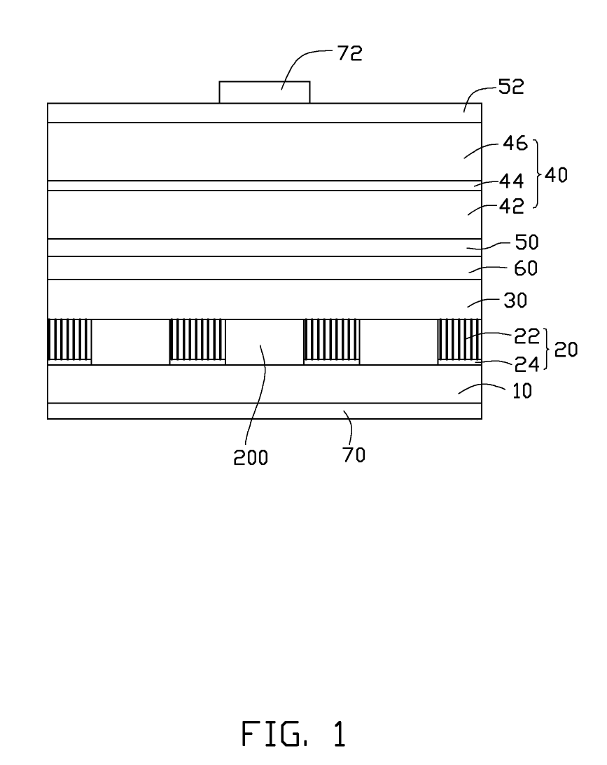

Referring to FIG. 1, a light emitting chip in accordance with a first embodiment of the present disclosure is disclosed. The light emitting chip includes a substrate 10, a heat conducting layer 20 formed on the substrate 10, a light emitting structure 40 and a connecting layer 30 connecting the heat conducting layer 20 with the light emitting structure 40.

The substrate 10 may be made of sapphire, SiC, Si, GaN or other suitable materials. Preferably, the substrate 10 is made of heat conductive materials such as SiC, Si or GaN in this embodiment, for increasing heat dissipation capability of the light emitting chip. The heat conducting layer 20 includes a catalyst layer 24 and a carbon nanotube layer 22. The material of the catalyst layer 24 may be selected from Fe, Co, Ni, Mo or other suitable transition metals. The catalyst layer 24 is used for providing growing medium for the carbon nanotube layer 22. The catalyst layer 24 can be grown on a top face of the substrate 10 via MOCVD (Metal-Organic Chemical Vapor Deposition) or other suitable methods. The catalyst layer 24 forms a plurality of areas on the substrate 10 which are spaced from each other by multiple gaps 200. The carbon nanotube layer 22 is vertically grown from the catalyst layer 24 by reaction of a gas combination containing CH₄, H₂, N₂ and Ar on top faces of the areas of the catalyst layer 24. The carbon nanotube layer 22 forms a plurality islands on the areas of the catalyst layer 24, respectively. The islands of the carbon nanotube layer 22 are also spaced from each other by the gaps 200. Each island of the carbon nanotube layer 22 is extended from the top face of a corresponding area of the catalyst layer 24 to a bottom face of the connecting layer 30.

The light emitting structure 40 includes a first semiconductor layer 42, a light emitting layer 44 and a second semiconductor layer 46. In this embodiment, the first semiconductor layer 42 is a P-type GaN layer, the second semiconductor layer 46 is an N-type GaN layer, and the light emitting layer 44 is a multi-quantum well GaN layer. The light emitting structure 40 is grown on a temporary substrate (not shown) by sequentially forming the second semiconductor layer 46, the light emitting layer 44 and the first semiconductor layer 42, and then connected to the heat conducting layer 20 via the connecting layer 30 in an inverted manner so that the first semiconductor layer 42 is close to the heat conducting layer 20. The temporary substrate is removed from the second semiconductor layer 46 by laser or milling to expose the second semiconductor layer 46.

A first transparent conductive layer 50 and a second transparent conductive layer 52 are formed on a bottom face of the first semiconductor layer 42 and a top face of the second semiconductor layer 46, respectively. The first and second transparent conductive layers 50, 52 may be made of ITO (Indium Tin Oxide) or an alloy of Ni/Au. The first and second transparent conductive layer 50, 52 can distribute current to uniformly flow through the first and second semiconductor layers 42, 46, respectively. The first transparent conductive layer 50 further forms a current conducting layer 60 on a bottom face thereof for conducting current within the light emitting chip. The current conducting layer 60 may be made of metal having a high reflective index, such as Au or Ag, for reflecting light downwardly emitted from the light emitting layer 44 towards the second transparent conductive layer 52, thereby increasing light-extracting efficiency of the light emitting chip. Alternatively, the current conducting layer 60 can also be in the form of electrically conductive DBR (Distributed Bragg Reflector) which is made by alternating multiple high refractive films with multiple low refractive films. The DBR layer can have a relatively high reflective efficiency approximate to 99% so that much more light can be reflected back towards the second transparent conductive layer 52. The second transparent conductive layer 52 forms a second electrode 72 on a top face thereof, and the substrate 10 forms a first electrode 70 on a bottom face thereof. The first electrode 70 and the second electrode 72 are used to join with other electrical structures (such as a golden pad for the first electrode 70 and a golden wire for the second electrode 72) so that the light emitting chip can electrically connect with a power source.

The connecting layer 30 is interposed between the current conducting layer 60 and the heat conducting layer 20 to attach the light emitting structure 40 to the heat conducting layer 20. The connecting layer 30 may be made of metal, transparent metal oxide or transparent glue which is electrically conductive. As the light emitting structure 40 is bonded to the heat conducting layer 20 via the connecting layer 30, a current flowing pathway from the first electrode 70 sequentially through the substrate 10, the heat conducting layer 20, the connecting layer 30, the current conducting layer 60, the first transparent conductive layer 50, the first semiconductor layer 42, the light emitting layer 44, the second semiconductor layer 46 and the second transparent layer 52 to the second electrode 72, is formed.

Since the carbon nanotubes have a relatively high heat conductive index more than 2000 W/m·K, the heat generated by the light emitting layer 44 can be effectively dissipated by the carbon nanotube layer 22. Furthermore, such vertical orientation of the carbon nanotubes can ensure that the heat is rapidly transferred to the substrate 10 from the light emitting structure 40 due to the heat conducting direction of the carbon nanotubes being identical to the grown direction of the carbon nanotubes.

A method for manufacturing the light emitting chip is also disclosed, which includes steps:

providing a substrate 10;

forming a heat conducting layer 20 on the substrate 10, wherein the heat conducting layer 20 includes a plurality of catalyst areas 24 and a plurality of carbon nanotube islands 22 extending upwardly from the catalyst areas, respectively;

attaching a light emitting structure 40 on the heat conducting layer 20 via a connecting layer 30, wherein the light emitting structure 40 includes a first semiconductor layer 42, a light emitting layer 44 and a second semiconductor layer 46 with a first transparent conductive layer 50 and a second transparent conductive layer 52 formed on the first semiconductor layer 42 and the second semiconductor layer 46, respectively; and

forming a first electrode 70 and a second electrode 72 on the substrate 10 and the second transparent conductive layer 52, respectively.

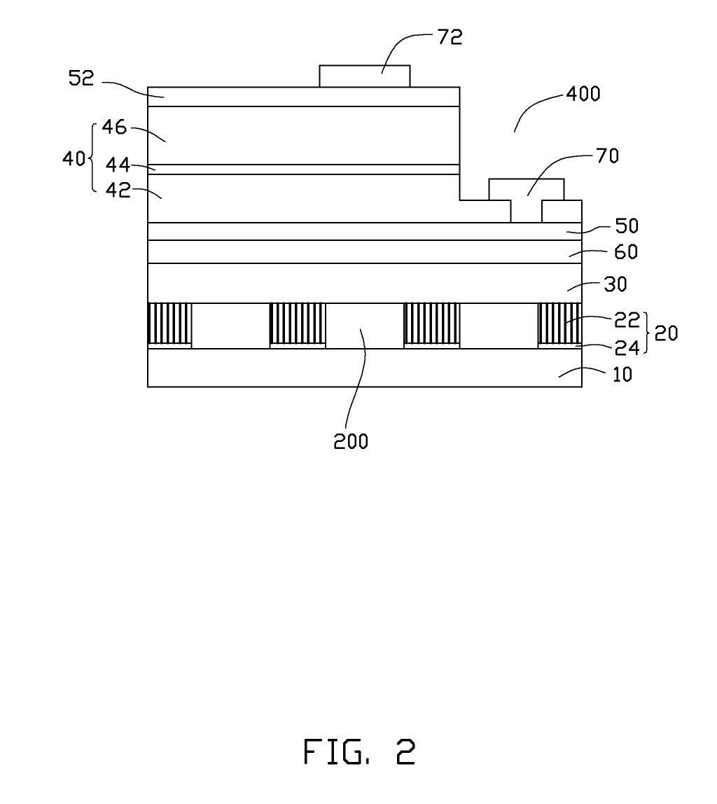

The substrate 10 of the light emitting chip in accordance with this embodiment is electrically conductive, whereby the first electrode 70 can be made on the bottom face of the substrate 10. However, when the substrate 10 is made of electrically nonconductive materials such as sapphire, the first electrode 70 cannot be formed on the substrate 10 and should be placed at other positions of the light emitting chip for ensuring continuous current conduction within the light emitting chip. FIG. 2 shows a light emitting chip in accordance with a second embodiment of the present disclosure which has a nonconductive substrate 10. The light emitting chip has a structure similar to that of the first embodiment except a location of the first electrode 70. The light emitting chip is etched to form a recess 400 in a lateral side thereof to expose the first semiconductor layer 42 and the first transparent conductive layer 50. The first electrode 70 is directly made on the first semiconductor layer 42 and connected to the first transparent conductive layer 50 mechanically and electrically.

It is believed that the present disclosure and its advantages will be understood from the foregoing description, and it will be apparent that various changes may be made thereto without departing from the spirit and scope of the present disclosure or sacrificing all of its material advantages, the examples hereinbefore described merely being preferred or exemplary embodiments.

What is claimed is:

1. A light emitting chip comprising:
a substrate;
a heat conducting layer formed on the substrate, the heat conducting layer comprising a vertically grown carbon nanotube layer; and
a light emitting structure connected to the heat conducting layer, the light emitting structure comprising a first semiconductor layer, a light emitting layer and a second semiconductor layer.

2. The light emitting chip as claimed in claim 1, wherein the carbon nanotube layer has a plurality of discrete islands spaced by multiple gaps.

3. The light emitting chip as claimed in claim 2, wherein the heat conducting layer comprises a catalyst layer supporting the carbon nanotube layer thereon.

4. The light emitting chip as claimed in claim 3, wherein the catalyst layer is divided by the gaps to a plurality of spaced areas.

5. The light emitting chip as claimed in claim 1 further comprising a first transparent conductive layer and a second transparent conductive layer formed on a bottom face of the first semiconductor layer and a top face of the second semiconductor layer, respectively.

6. The light emitting chip as claimed in claim 5, wherein the heat conducting layer is connected to the light emitting structure via a connecting layer.

7. The light emitting chip as claimed in claim 6 further comprising a current conducting layer formed on a bottom face of the first transparent conductive layer, wherein the current conducting layer is located between the first transparent conductive layer and the connecting layer.

8. The light emitting chip as claimed in claim 7, wherein the current conducting layer is a light reflective layer.

9. The light emitting chip as claimed in claim 8, wherein the current conducting layer is a distributed bragg reflector (DBR).

10. The light emitting chip as claimed in claim 5 further comprising a first electrode formed on a bottom face of the substrate and a second electrode formed on a top face of the second transparent conductive layer.

11. The light emitting chip as claimed in claim 5 further comprising a first electrode directly connected to the first semiconductor layer and the first transparent conductive layer exposed in a recess defined in the light emitting chip and a second electrode formed on a top face of the second transparent conductive layer.

12. A method for manufacturing a light emitting chip, comprising steps:
providing a substrate;
forming a heat conducting layer on the substrate, the heat conducting layer comprising a vertically grown carbon nanotube layer; and
connecting a light emitting structure to the heat conducting layer via a connecting layer, the light emitting structure comprising a first semiconductor layer, a second semiconductor layer and a light emitting layer located between the first semiconductor layer and the second semiconductor layer.

13. The method as claimed in claim 12, wherein the carbon nanotube layer has a plurality of islands spaced from each other by multiple gaps.

14. The method as claimed in claim 13, wherein the heat conducting layer comprises a catalyst layer having a plurality of areas joining with the islands of the carbon nanotube layer, respectively.

15. The method as claimed in claim 14, wherein the catalyst layer is located between the carbon nanotube layer and the substrate.

16. The method as claimed in claim 12, wherein the light emitting chip comprises a first transparent conductive layer connected to a bottom face of the first semiconductor layer and a second transparent conductive layer connected to a top face of the second semiconductor layer.

17. The method as claimed in claim 16, wherein the light emitting chip comprises a current conducting layer connected to and sandwiched between the first transparent conductive layer and the connecting layer.

18. The method as claimed in claim 17, wherein the current conductive layer is a light reflective layer.

19. The method as claimed in claim 16, wherein the light emitting chip comprises a first electrode formed on a bottom face of the substrate and a second electrode formed on a top face of the second transparent conductive layer.

20. The method as claimed in claim 16, wherein the light emitting chip comprises a second electrode formed on a top face of the second transparent conductive layer and a first electrode directly connected to the first semiconductor layer and the first transparent conductive layer.
